(19) United States
(12) Patent Application Publication
(10) Pub. No.: US 2025/0360838 A1
(43) Pub. Date: Nov. 27, 2025

(54) SYSTEM AND METHOD FOR PREVENTING CONDENSATION IN VEHICLE POWER CONTROL UNIT

(71) Applicants: Hyundai Motor Company, Seoul (KR); Kia Corporation, Seoul (KR)

(72) Inventors: Seung Bae JEONG, Hwaseong-si (KR); Byung Kwon Han, Hwaseong-si (KR); Hyong Joon Park, Hwaseong-si (KR); Ok Geun Ha, Hwaseong-si (KR)

(73) Assignees: Hyundai Motor Company, Seoul (KR); Kia Corporation, Seoul (KR)

(21) Appl. No.: 18/930,814

(22) Filed: Oct. 29, 2024

(30) Foreign Application Priority Data
May 24, 2024 (KR) 10-2024-0067843

(51) Int. Cl. B60L 58/27; B60K 1/00; B60K 1/04

(52) U.S. Cl. CPC B60L 58/27; B60K 1/04; B60K 2001/008; B60L 2240/545; B60L 2240/662

(57) ABSTRACT

In a system and method for preventing condensation that occurs in a vehicle power control unit due to traveling wind, etc., with a heating wire mounted on the external surface of a housing of the power control unit, the internal temperature and the external temperature of the power control unit are detected and the heating wire is turned on when the difference between the detected internal temperature and external temperature of the power control unit is determined to be greater than or equal to a predetermined value, preventing condensation on the internal surface of the housing of the power control unit.

### CROSS-REFERENCE TO RELATED APPLICATION

The present application claims priority to Korean Patent Application No. 10-2024-0067843, filed on May 24, 2024, the entire contents of which is incorporated herein for all purposes by this reference.

### BACKGROUND OF THE PRESENT DISCLOSURE

### Field of the Present Disclosure

The present disclosure relates to a system and method for preventing condensation in a vehicle power control unit. More particularly, the present disclosure relates to a system and method for preventing condensation that occurs in a vehicle power control unit due to traveling wind, etc.

### Description of Related art

An engine compartment of an eco-friendly vehicle, such as a hybrid vehicle, is provided with a hybrid power control unit (HPCU), configured to control power supply to a motor, as well as a motor for traveling.

The hybrid power control unit (hereinafter referred to as a “power control unit”) mounted in an engine compartment is a type of control device configured not only to perform power distribution control between the engine and the motor, regenerative braking control, and motor and inverter control, but also to convert battery voltage for driving the motor into alternating-current voltage.

Referring to FIG. 1, a power control unit 10 includes a housing 12 having a predetermined shape, a power module 14 mounted within the housing 12 and configured to convert battery voltage into alternating-current voltage, and a cover 16 assembled to a lower opening in the housing 12.

When the cover 16 is assembled to the lower opening in the housing 12 after the power module 14 and various electrical components are assembled inside the housing 12, a watertight sealant is applied between the housing 12 and the cover 16, achieving insulation protection for the power module 14 and various electrical components.

Moreover, because the interior of the housing 12 is completely sealed from the outside thereof by the sealant applied between the housing 12 and the cover 16, there are no water molecules inside the housing, and thus condensation that causes insulation breakdown does not occur.

However, a small amount of fine water molecules may be introduced into the housing 12 along the surfaces of an electrical connector and a wire, which are connected to the housing 12 of the power control unit 10, and as the durability of the housing deteriorates, the number of water molecules being introduced into the housing 12 may increase.

Accordingly, when the power control unit 10 is exposed to cold traveling wind flowing into the engine compartment while the vehicle is traveling, condensation where water droplets form on the internal surface of the housing 12 of the power control unit 10 may occur.

For example, when cold traveling wind touches the external surface of the housing 12 of the power control unit 10 while the vehicle is traveling, in a state in which the internal temperature of the housing 12 is increased to about 80° C. or more as the power module 14 and various electrical components in the power control unit 10 operate, the difference between the internal temperature and the external temperature of the housing 12 becomes large, which may cause condensation where water droplets form on the internal surface of the housing 12 of the power control unit 10.

The condensation on the internal surface of the housing 12 of the power control unit 10 may lead problems such as insulation breakdown of the power module 14 and various electrical components mounted within the housing 12.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a system and method for preventing condensation in a vehicle power control unit in which the internal temperature and the external temperature of a housing of the power control unit mounted in an engine compartment in the vehicle are detected and a heating wire mounted on the external surface of the housing is turned on when the difference between the detected internal temperature and external temperature of the power control unit is determined to be greater than or equal to a predetermined value, preventing condensation on the internal surface of the housing of the power control unit.

In one aspect, the present disclosure provides a system for preventing condensation in a power control unit for a vehicle. Here, the system may include the power control unit including a housing and a power module mounted within the housing, a heating wire mounted on the external surface of the housing, and a controller operatively connected to the heating wire and configured to detect the internal temperature and the external temperature of the housing and to turn on the heating wire when the difference between the internal temperature and the external temperature of the housing is greater than or equal to a predetermined value.

In an exemplary embodiment of the present disclosure, the controller may detect the internal temperature and the external temperature of the housing using a predetermined temperature estimation model.

In another exemplary embodiment of the present disclosure, the predetermined temperature estimation model of the controller may include a first model configured to determine the internal temperature of the housing, and a second model configured to determine the external temperature of the housing.

In various exemplary embodiments of the present disclosure, the first model may be modeled to determine the internal temperature of the housing using a heating temperature of the power module mounted within the housing and a coolant temperature detected by a coolant temperature sensor of the vehicle as variables of the first model.

In various exemplary embodiments of the present disclosure, the second model may be modeled to determine the external temperature of the housing using an outdoor temperature detected by an outdoor temperature sensor of the vehicle and a traveling speed detected by a speed sensor of the vehicle as variables of the second model.

In another aspect, the present disclosure provides a method for preventing condensation in a power control unit for a vehicle. Here, the method may include detecting, by a controller, the internal temperature and the external temperature of a housing of the power control unit, determining, by the controller, the difference between the internal temperature and the external temperature of the housing, and turning on a heating wire mounted on the external surface of the housing by a control signal of the controller when the difference between the internal temperature and the external temperature of the housing is greater than or equal to a predetermined value.

In an exemplary embodiment of the present disclosure, the detecting, by the controller, the internal temperature and the external temperature of the housing may be performed using a predetermined temperature estimation model.

In another exemplary embodiment of the present disclosure, the predetermined temperature estimation model may include a first model configured to determine the internal temperature of the housing and a second model configured to determine the external temperature of the housing, and may be executably stored in the controller.

In various exemplary embodiments of the present disclosure, the first model may be modeled to determine the internal temperature of the housing using a heating temperature of the power module mounted within the housing and a coolant temperature detected by a coolant temperature sensor of the vehicle as variables of the first model.

In various exemplary embodiments of the present disclosure, the second model may be modeled to determine the external temperature of the housing using an outdoor temperature detected by an outdoor temperature sensor of the vehicle and a traveling speed detected by a speed sensor of the vehicle as variables of the second model.

Other aspects and embodiments of the present disclosure are discussed infra.

It is to be understood that the term “vehicle” or “vehicular” or other similar terms as used herein are inclusive of motor vehicles in general, such as passenger automobiles including sports utility vehicles (SUV), buses, trucks, various commercial vehicles, watercraft including a variety of boats and ships, aircraft, and the like, and include hybrid vehicles, electric vehicles, plug-in hybrid electric vehicles, hydrogen-powered vehicles, and other alternative fuel vehicles (e.g., fuels derived from resources other than petroleum). As referred to herein, a hybrid vehicle is a vehicle that has two or more sources of power, for example, a vehicle powered by both gasoline and electricity.

The above and other features of the present disclosure are discussed infra.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a schematic view exemplarily illustrating a power control unit of the related art and the mounting position thereof;

FIG. 2 is a schematic cross-sectional view exemplarily illustrating a vehicle power control unit according to an exemplary embodiment of the present disclosure;

FIG. 3 is a control block diagram showing a condensation prevention system for a vehicle power control unit according to an exemplary embodiment of the present disclosure; and

FIG. 4 is a flowchart showing a method for preventing condensation in a vehicle power control unit according to an exemplary embodiment of the present disclosure.

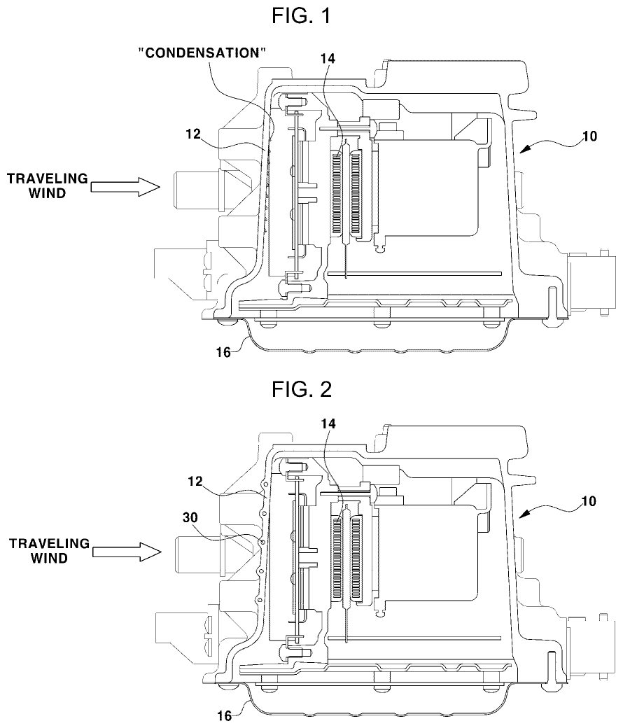

It should be understood that the appended drawings are not necessarily to scale, presenting a somewhat simplified representation of various exemplary features illustrative of the basic principles of the present disclosure. The predetermined design features of the present disclosure, including, for example, predetermined dimensions, orientations, locations, and shapes, will be determined in portion by the intended application and usage environment.

In the figures, the reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Descriptions of specific structures or functions presented in the exemplary embodiments of the present disclosure are merely exemplary for explaining the exemplary embodiments according to the concept of the present disclosure, and the exemplary embodiments according to the concept of the present disclosure may be implemented in various forms. Furthermore, the descriptions should not be construed as being limited to the exemplary embodiments described herein, and should be understood to include all modifications, equivalents and substitutes falling within the idea and scope of the present disclosure.

In the present specification, the terms “first,” “second,” etc. may be used to describe various components, but the components are not limited to the terms. These terms are only used to distinguish one component from another. For example, a first component could be termed a second component, and similarly, a second component could be termed a first component, without departing from the scope of exemplary embodiments of the present disclosure.

Throughout the specification, like reference numerals indicate like components. The terminology used herein is for illustrating embodiments and is not intended to limit the present disclosure. In the present specification, the singular form includes plural forms unless specified otherwise. The terms “includes” and/or “including” used in the present specification mean that the cited component, step, operation, and/or element does not exclude the presence or addition of one or more of other components, steps, operations, and/or elements.

Hereinafter, various exemplary embodiments of the present disclosure are described in detail with reference to the accompanying drawings.

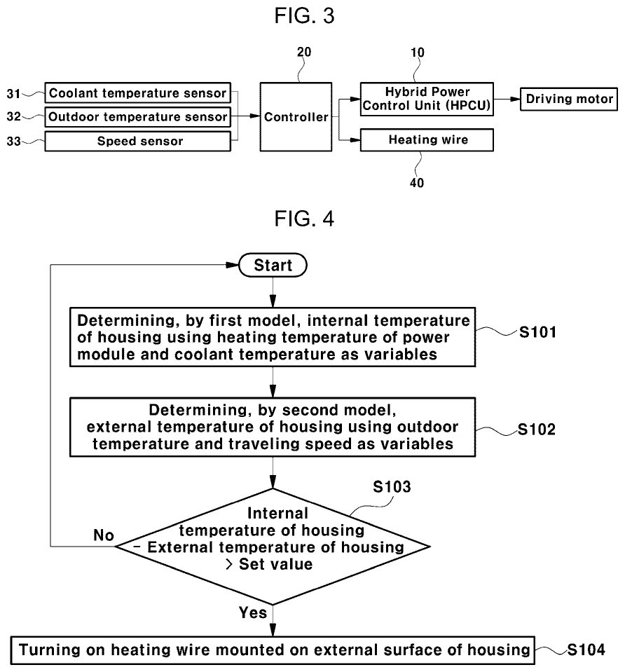

FIG. 2 is a schematic cross-sectional view exemplarily illustrating a vehicle power control unit according to an exemplary embodiment of the present disclosure, and FIG. 3 is a control block diagram showing a condensation prevention system for a vehicle power control unit according to an exemplary embodiment of the present disclosure.

As illustrated in FIG. 2, a power control unit 10 includes a housing 12 including a predetermined shape, a power module 14 mounted within the housing 12 and configured to convert battery voltage into alternating-current voltage, and a cover 16 assembled to a lower opening in the housing 12.

Moreover, the housing 12 has mounted therein, in addition to the power module 14, various electrical components and has formed therein a coolant circulation passage configured to cool the power module 14 and various electrical components.

Accordingly, even when the power module 14 and various electrical components generate heat during operation, the same may be cooled by the coolant circulating through the coolant circulation passage in the housing 12.

Moreover, when the cover 16 is assembled to the lower opening in the housing 12 after the power module 14 and various electrical components are assembled inside the housing 12, a watertight sealant is applied between the housing 12 and the cover 16, achieving insulation protection for the power module 14 and various electrical components.

However, when a small amount of fine water molecules is introduced into the housing 12 along the surfaces of an electrical connector and a wire, which are connected to the housing 12 of the power control unit 10, and the power control unit 10 is exposed to cold traveling wind flowing into an engine compartment, condensation that causes insulation breakdown may occur on the internal surface of the housing 12 of the power control unit 10.

The internal temperature of the housing 12 may increase due to the heat generated in the power module 14 and various electrical components and the external temperature of the housing 12 may decrease due to exposure to cold traveling wind, and due to the difference between the internal temperature and the external temperature of the housing 12, condensation may occur on the internal surface of the housing 12.

To prevent the condensation, a heating wire 30 configured to be turned on or off by a control signal from the controller 20 is mounted on the external surface of the housing 12.

The heating wire 30 may be mounted on an area in the external surface of the housing 12 which is directly exposed to traveling wind, which causes condensation.

In an exemplary embodiment of the present disclosure, the heating wire 30 may be imbedded in a body of the housing 12.

The controller 20 is configured to detect the internal temperature and the external temperature of the housing 12 and to turn on the heating wire 30 when the difference between the detected internal temperature and external temperature of the housing is greater than or equal to a predetermined value.

To the present end, the controller 20 is configured to detect the internal temperature and the external temperature of the housing 12 that change while the vehicle is traveling by use of a pre-modeled temperature estimation model.

The temperature estimation model of the controller 20 may include a first model configured to determine the internal temperature of the housing 12 and a second model configured to determine the external temperature of the housing 12. The temperature estimation model may be stored in a memory unit of the controller 20 and may be executed by a processor of the controller 20.

The first model may be pre-modeled to determine the internal temperature of the housing 12 using the heating temperature of the power module 14 mounted inside the housing 12 and a coolant temperature (e.g., the temperature of coolant circulating through the coolant circulation passage in the housing) detected by a coolant temperature sensor 31 of the vehicle as variables and may be stored in the memory unit of the controller 20. The first model may be executed by the processor of the controller 20.

The second model may be pre-modeled to determine the external temperature of the housing 12 using the outdoor temperature detected by an outdoor temperature sensor 32 of the vehicle and a traveling speed detected by a speed sensor 33 of the vehicle as variables and may be stored in the memory unit of the controller 20. The second model may be executed by the processor of the controller 20.

Meanwhile, the internal temperature and the external temperature of the housing 12 may be directly detected by temperature sensors which may be mounted on the internal and external surfaces of the housing 12. However, it is preferable to determine the internal temperature and the external temperature of the housing 12 using the first model and the second model of the controller 20.

Because the internal temperature of the housing 12 may change rapidly due to the change in the heating temperature of the power module 14 and in the temperature of the coolant flowing through the coolant circulation passage in the housing 12 and the external temperature of the housing 12 may change rapidly due to the change in outdoor temperature and vehicle traveling speed that affects the temperature and speed of the traveling wind, it is preferable to determine the internal temperature and the external temperature of the housing 12 using the first model and the second model of the controller 20.

Here, a method for preventing condensation in the power control unit of the present disclosure including the above-mentioned structure is performed sequentially as follows.

FIG. 4 is a flowchart showing the method for preventing condensation in the vehicle power control unit according to an exemplary embodiment of the present disclosure.

First, with the power control unit 10 mounted in the engine compartment, a step of detecting, by the temperature estimation model of the controller 20, the internal temperature and the external temperature of the housing 12 of the power control unit 10 while the vehicle is traveling is performed.

Here, the internal temperature of the housing 12 is determined by the first model of the temperature estimation model of the controller 20.

The first model is configured to determine the internal temperature of the housing 12 by use of the heating temperature of the power module 14 mounted inside the housing 12 and a coolant temperature (e.g., the temperature of coolant circulating through the coolant circulation passage in the housing) detected by the coolant temperature sensor 31 of the vehicle as variables, at step S101.

The external temperature of the housing 12 is determined by the second model of the temperature estimation model of the controller 20.

The second model is configured to determine the external temperature of the housing 12 by use of the outdoor temperature detected by the outdoor temperature sensor 32 of the vehicle and the traveling speed detected by the speed sensor 33 of the vehicle as variables, at step S102.

Thereafter, the controller 20 is configured to determine a difference between the internal temperature and the external temperature of the housing 12, and compares the difference with a predetermined value, which is a predetermined reference value, at step S103.

When the difference between the internal temperature and the external temperature of the housing 12 is greater than or equal to the predetermined value, turning on the heating wire 30 mounted on the external surface of the housing 12 by a control signal of the controller 20 is performed at step S104.

Because the heating wire 30 mounted on the external surface of the housing 12 is turned on to increase the external temperature of the housing 12, i.e., the temperature of the external surface of the housing 12 which is exposed to the traveling wind, the difference between the internal temperature and the external temperature of the housing 12 may be adjusted to be smaller than the predetermined value at which condensation is not occurred, preventing condensation on the internal surface of the housing 12 of the power control unit 10.

Accordingly, condensation on the internal surface of the housing 12 of the power control unit 10 is prevented, ensuring the electrical insulation performance of the power module 14 and various electrical components mounted within the housing 12 and improving the durability of the power control unit 10.

As is apparent from the above description, the present disclosure provides the following effects.

First, the internal temperature and the external temperature of the housing of the power control unit are detected, and the heating wire mounted on the external surface of the housing is turned on when the difference between the detected internal temperature and external temperature is determined to be greater than or equal to the predetermined value, preventing condensation on the internal surface of the housing of the power control unit.

Second, condensation on the internal surface of the housing of the power control unit is prevented, ensuring the electrical insulation performance of the power module and various electrical components mounted within the housing and improving the durability of the power control unit.

Furthermore, the term related to a control device such as “controller”, “control apparatus”, “control unit”, “control device”, “control module”, “control circuit”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Software implementations may include software components (or elements), object-oriented software components, class components, task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well-known to a person including ordinary knowledge in the art.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, a plurality of operations may be merged, or any operation may be divided, and a predetermined operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A system for preventing condensation in a power control unit for a vehicle, the system comprising:
the power control unit including a housing and a power module mounted within the housing;
a heating wire mounted on an external surface of the housing; and
a controller operatively connected to the heating wire and configured to detect an internal temperature and an external temperature of the housing and to turn on the heating wire in response that a difference between the internal temperature and the external temperature of the housing is greater than or equal to a predetermined value.

2. The system of claim 1, wherein the controller is configured to detect the internal temperature and the external temperature of the housing using a predetermined temperature estimation model.

3. The system of claim 2, wherein the predetermined temperature estimation model of the controller includes:
a first model configured to determine the internal temperature of the housing; and
a second model configured to determine the external temperature of the housing.

4. The system of claim 3, wherein the first model is modeled to determine the internal temperature of the housing using a heating temperature of the power module mounted within the housing and a coolant temperature detected by a coolant temperature sensor operatively connected to the controller as variables of the first model.

5. The system of claim 3, wherein the second model is modeled to determine the external temperature of the housing using an outdoor temperature detected by an outdoor temperature sensor operatively connected to the controller and a traveling speed detected by a speed sensor operatively connected to the controller as variables of the second model.

6. The system of claim 3, wherein the heating wire is imbedded within a body of the housing.

7. A method for preventing condensation in a power control unit of a vehicle, the method comprising:
detecting, by a controller, an internal temperature and an external temperature of a housing of the power control unit;
determining, by the controller, a difference between the internal temperature and the external temperature of the housing; and
turning on a heating wire mounted on an external surface of the housing and operatively connected to the controller, by a control signal of the controller in response that the difference between the internal temperature and the external temperature of the housing is greater than or equal to a predetermined value.

8. The method of claim 7, wherein the detecting, by the controller, the internal temperature and the external temperature of the housing is performed using a predetermined temperature estimation model.

9. The method of claim 8, wherein the predetermined temperature estimation model includes a first model configured to determine the internal temperature of the housing and a second model configured to determine the external temperature of the housing, and is executably stored in the controller.

10. The method of claim 9, wherein the first model is modeled to determine the internal temperature of the housing using a heating temperature of the power module mounted within the housing and a coolant temperature detected by a coolant temperature sensor operatively connected to the controller as variables of the first model.

11. The method of claim 9, wherein the second model is modeled to determine the external temperature of the housing using an outdoor temperature detected by an outdoor temperature sensor operatively connected to the controller and a traveling speed detected by a speed sensor operatively connected to the controller as variables of the second model.
